(19) United States
(12) Patent Application Publication
(10) Pub. No.: US 2024/0429102 A1
(43) Pub. Date: Dec. 26, 2024

(54) SEMICONDUCTOR STRUCTURE AND MANUFACTURING METHOD THEREOF

(71) Applicant: TAIWAN SEMICONDUCTOR MANUFACTURING COMPANY, LTD., Hsinchu (TW)

(72) Inventors: Wei-Yip LOH, Hsinchu City (TW); Hung-Hsu Chen, Tainan City (TW); Chih-Chien Chi, Hsinchu City (TW); Harry Chien, Chandler, AZ (US); Chih-Wei Chang, Hsinchu County (TW)

(73) Assignee: TAIWAN SEMICONDUCTOR MANUFACTURING COMPANY, LTD., Hsinchu (TW)

(21) Appl. No.: 18/338,715

(22) Filed: Jun. 21, 2023

(51) Int. Cl. H01L 21/8234; H01L 27/088; H01L 29/06; H01L 29/423; H01L 29/45; H01L 29/66; H01L 29/775

(52) U.S. Cl. CPC H01L 21/823475; H01L 27/088; H01L 29/0673; H01L 29/42392; H01L 29/456; H01L 29/66439; H01L 29/775

(57) ABSTRACT

A method includes forming a bottom-tier transistor and a top-tier transistor over the bottom-tier transistor, the top-tier transistor comprising a first channel layer, a first gate structure around the first channel layer, and a plurality of first source/drain regions on opposite sides of the first channel layer; forming a first dielectric layer over the first source/drain regions of the top-tier transistor; etching the first dielectric layer to form a first opening exposing one of the first source/drain regions of the top-tier transistor; selectively forming a first metal silicide on the one of the first source/drain regions; selectively forming a first metal cap on the first metal silicide and not on the first dielectric layer; forming a front-side contact on the first metal cap.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-17F illustrate schematic views of intermediate stages of semiconductor structures in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

In the course of IC evolution, functional density (i.e., the number of interconnected devices per chip area) has generally increased while geometry size (i.e., the smallest component (or line) that can be created using a fabrication process) has decreased. To improve the functional density of the IC structure, a complementary FET (CFET) in which a p-type FET and an n-type FET are vertically stacked has been proposed. A metal silicide can be formed on the source/drain region through a dielectric-defined source/drain opening to improve the silicide-diffusion contact resistance (Rcsd) of the IC structure. However, due to the small landing area of the source/drain region in the dielectric-defined source/drain opening, the metal silicide and the following source/drain contact material is hard to form on the source/drain region through the dielectric-defined source/drain opening, which in turn deteriorates the silicide-diffusion contact resistance of the IC structure, and thus the performance of the IC structure may be reduced.

Therefore, the present disclosure in various embodiments provides a method to selectively form a metal silicide and a metal cap on a source/drain region of a transistor other than the surrounding dielectric by a deposition process, such as CVD or ALD process. As such, the deposition material of the metal silicide and the deposition material of the metal cap can be easily formed on the source/drain region through the source/drain opening in a limited deposition area. In addition, because the metal silicide and the metal cap can be only formed on the source/drain region other than the surrounding dielectric, the metal silicide and the metal cap occupy less space in the source/drain opening, which in turn facilitates the following metal filling in the source/drain opening, and thus the silicide-diffusion contact resistance of the IC structure can be improved.

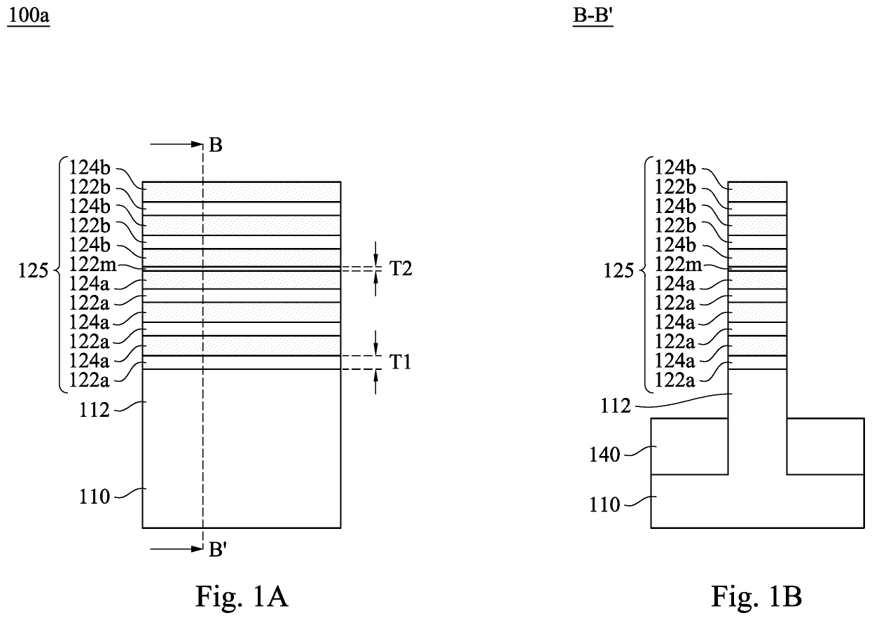

Reference is made to FIGS. 1A-16B. FIGS. 1A, 2A, 3A, 4A, 5A, 6A, 7A, 8A, 9A, 10A, 11A, 12A, 13A, 14A, 15A, 16A, and 17A illustrate cross-sectional views of intermediate stages in the formation of a semiconductor structure 100a in accordance with some embodiments. FIGS. 1B, 2B, 3B, 4B, 5B, 6B, 7B, 8B, 9B, 10B, 11B, 12B, 13B, 14B. 15B. 16B, and 17B illustrate cross-sectional views obtained from the reference cross-section B-B′ in FIGS. 1A, 2A, 3A, 4A, 5A, 6A, 7A, 8A, 9A, 10A, 11A, 12A, 13A, 14A, 15A, 16A, and 17A, respectively.

Reference is made to FIGS. 1A and 1B. An epitaxial stack is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 110 may include a semiconductor-on-insulator (SOI) structure such as a buried dielectric layer. Also alternatively, the substrate 110 may include a buried dielectric layer such as a buried oxide (BOX) layer, such as that formed by a method referred to as separation by implantation of oxygen (SIMOX) technology, wafer bonding, SEG, or another appropriate method.

The epitaxial stack includes epitaxial layers 122a, 122b, 122m of a first composition interposed by epitaxial layers 124a, 124b of a second composition. The first and second compositions can be different. In some embodiments, the epitaxial layers 122a, 122b, 122m may be made of SiGe, and the epitaxial layers 124a, 124b may be made of silicon (Si). However, other embodiments are possible including those that provide for a first composition and a second composition having different etch selectivity.

The epitaxial layers 124a and 124b or portions thereof may form nanostructure channel(s) of the nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The use of the epitaxial layers 124a and 124b to define a channel or channels of a device is further discussed below. In FIGS. 1A and 1B, the epitaxial layers 124b are disposed above the epitaxial layers 124a. It is noted that three layers of the epitaxial layers 124a and three layers of the epitaxial layers 124b are arranged as illustrated in FIGS. 1A and 1B, which is for illustrative purposes only and not intended to be limiting beyond what is specifically recited in the claims. It can be appreciated that any number of epitaxial layers can be formed in the epitaxial stack; the number of layers depending on the desired number of channels regions for the transistor. In some embodiments, the number of each of the epitaxial layers 124a and 124b can be between 2 and 10.

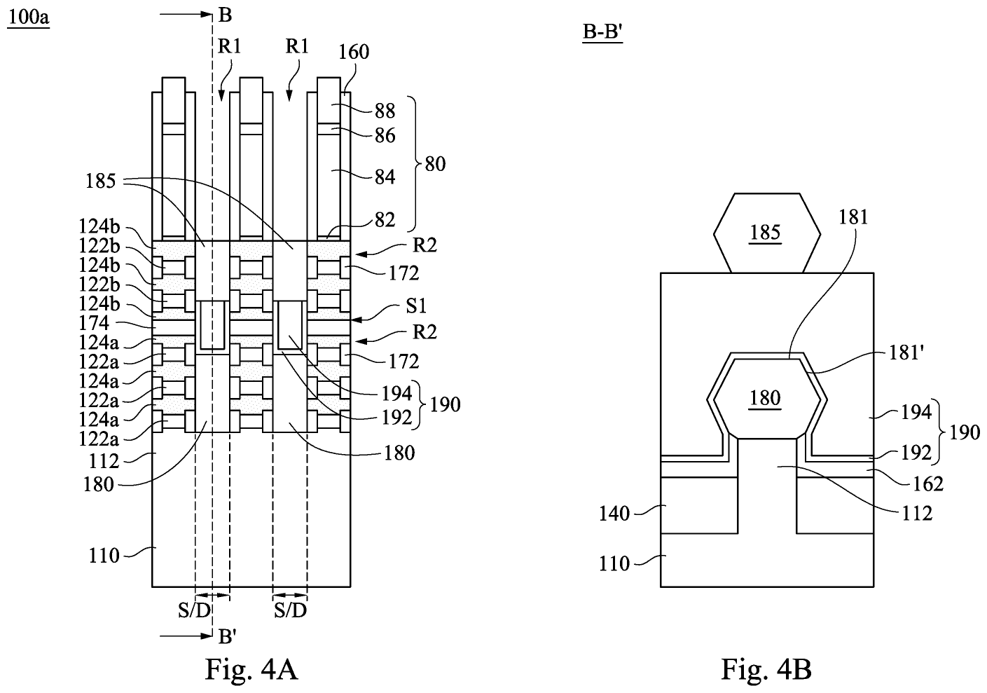

The epitaxial layers 122a are interposed by the epitaxial layers 124a, the epitaxial layers 122b are interposed by the epitaxial layers 124b, and the epitaxial layer 122m is between the epitaxial layers 124a and 124b. In some embodiments, the epitaxial layers 122a and 122b have substantially the same thickness T1, and the epitaxial layer 122m has a thickness T2 less than the thickness T1. In some embodiments, the thickness T2 is determined by the thickness of the isolation structure 190 (see FIGS. 4A and 4B) and is in a range of about 20 nm to about 1000 nm.

As described in more detail below, the epitaxial layers 124a and 124b may serve as channel region(s) for a subsequently-formed semiconductor device and the thickness is chosen based on device performance considerations. The epitaxial layers 122a, 122b, and 122m in channel regions(s) may eventually be removed and serve to define a vertical distance between adjacent channel region(s) for a subsequently-formed multi-gate device and the thickness is chosen based on device performance considerations. Accordingly, the epitaxial layers 122a, 122b, and 122m may also be referred to as sacrificial layers, and epitaxial layers 124a and 124b may also be referred to as channel layers. In some embodiments, the epitaxial layers 124a and 124b can be interchangeably referred to as channel regions or channel patterns.

By way of example, epitaxial growth of the layers of the epitaxial stack may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 124a and 124b include the same material as the substrate 110. In some embodiments, the epitaxial layers 122a, 122b, 122m and 124a, 124b include a different material than the substrate 110. As stated above, in at least some examples, the epitaxial layers 122a, 122b, and 122m include an epitaxially grown silicon germanium (SiGe) layer and the epitaxial layers 124a and 124b include an epitaxially grown silicon (Si) layer. Alternatively, in some embodiments, either of the epitaxial layers 122a, 122b, 122m and 124a, 124b may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP, AlInAs, AlGaAs, InGaAs, GaInP, and/or GaInAsP, III-V, or combinations thereof. As discussed, the materials of the epitaxial layers 122a, 122b, 122m and 124a, 124b may be chosen based on providing differing oxidation and/or etching selectivity properties.

In FIGS. 1A and 1B, at least one fin structure 125 extending from the substrate 110 is formed. In various embodiments, the fin structure 125 includes a protruding portion 112 formed from the substrate 110 and portions of each of the epitaxial layers of the epitaxial stack including epitaxial layers 122a, 122b, 122m and 124a, 124b. The fin structure 125 may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fin structure 125 by etching the epitaxial stack. The etching process can include dry etching, wet etching, reactive ion etching (RIE), and/or other suitable processes. Subsequently, an etch process forms trenches 102 into the substrate 110, thereby leaving the fin structure 125. The trenches 102 may be etched using a dry etch (e.g., reactive ion etching), a wet etch, and/or combination thereof. Numerous other embodiments of methods to form the fins on the substrate may also be used including, for example, defining the fin region (e.g., by mask or isolation regions) and epitaxially growing the epitaxial stack in the form of the fin structure 125.

Next, as illustrated in FIGS. 1A and 1B, isolation structures 140 are formed to surround the fin structure 125. The isolation structures 140 may include a liner oxide (not shown). The liner oxide may be formed of a thermal oxide formed through a thermal oxidation of a surface layer of the substrate 110. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). The isolation structures 140 may also include a dielectric material over the liner oxide, and the dielectric material may be formed using flowable chemical vapor deposition (FCVD), spin-on coating, or the like. Subsequently, the isolation structures 140 are recessed, so that the top portion of the fin structure 125 protrudes higher than the top surfaces of the neighboring isolation structures 140. The etching may be performed using a dry etching process, wherein NH₃ and NF₃ are used as the etching gases. During the etching process, plasma may be generated. Argon may also be included. In accordance with alternative embodiments of the present disclosure, the recessing of the isolation structures 140 is performed using a wet etch process. The etching chemical may include diluted HF, for example.

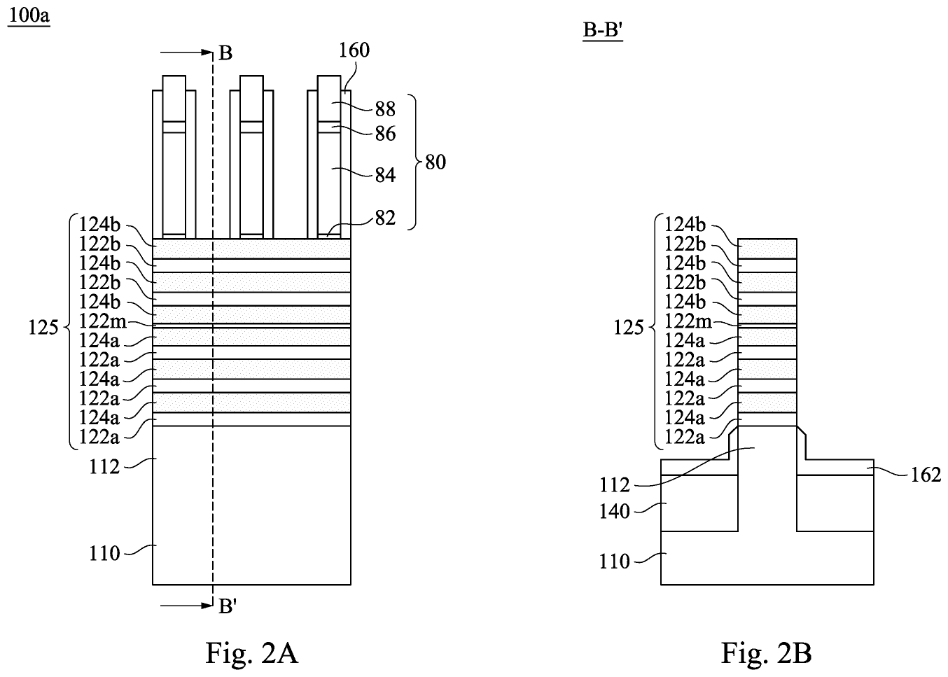

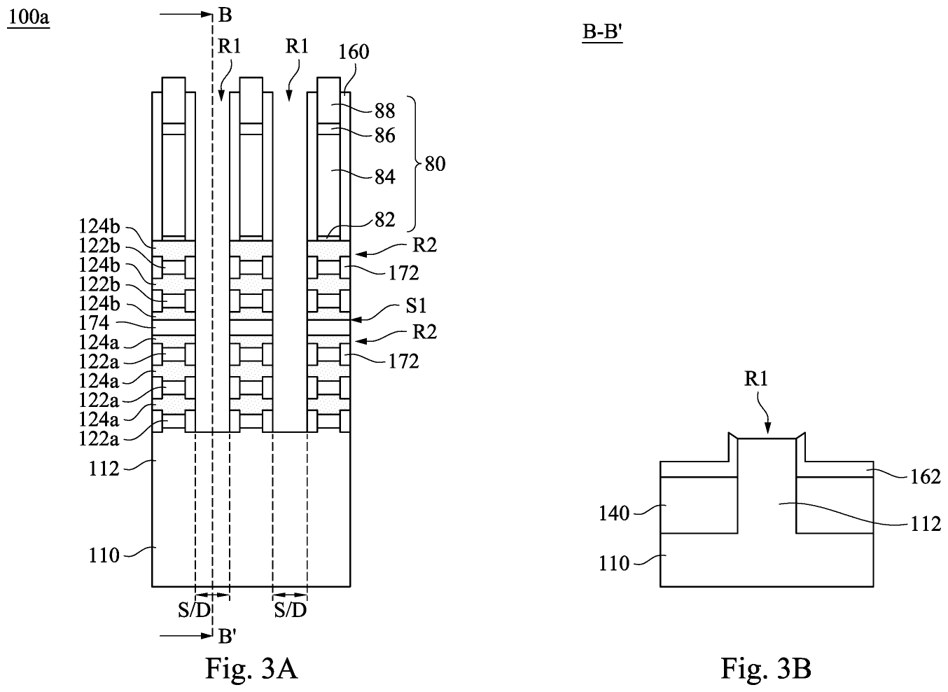

Reference is made to FIGS. 2A and 2B. At least one dummy gate structure 150 is formed over the substrate 110 and is partially disposed over the fin structure 125. The portion of the fin structure 125 underlying the dummy gate structure 150 may be referred to as the channel region. The dummy gate structure 150 may also define source/drain regions S/D (labeled in FIG. 3A) of the fin structure 125, for example, the regions of the fin structure 125 adjacent and on opposing sides of the channel region.

Dummy gate formation operation forms a dummy gate dielectric layer, a dummy gate electrode layer and a hard mask which may include multiple layers (e.g., an oxide layer and a nitride layer) over the dummy gate electrode layer. The hard mask is then patterned, followed by patterning the dummy gate electrode layer by using the patterned hard mask as an etch mask. The etch process may include a wet etch, a dry etch, and/or combinations thereof. As such, a dummy gate structure 150 including a dummy gate dielectric layer 152, a dummy gate electrode layer 154 and a hard mask (e.g., an oxide layer 156 and a nitride layer 158) is formed.

In some embodiments, the dummy gate dielectric layer 152 may be made of a dielectric material such as silicon nitride (SiN), silicon oxide (SiO₂), silicon carbo-nitride (SiCN), silicon oxynitride (SiON), silicon oxy-carbo-nitride (SiOCN), or the like, and may have a single-layer structure or a multi-layer structure including a plurality of dielectric layers. In some embodiments, the dummy gate dielectric layer 152 may be made of high-k dielectric materials, such as metal oxides, transition metal-oxides, or the like. Examples of the high-k dielectric material include, but are not limited to, hafnium oxide (HfO₂), hafnium silicon oxide (HfSiO), hafnium tantalum oxide (HfTaO), hafnium titanium oxide (HfTiO), hafnium zirconium oxide (HfZrO), zirconium oxide, titanium oxide, aluminum oxide, hafnium dioxide-alumina (HfO₂—Al₂O₃) alloy, or other applicable dielectric materials. In some embodiments, the dummy gate dielectric layer 152 is an oxide layer. The dummy gate dielectric layer 152 may be formed by a deposition processes, such as chemical vapor deposition (CVD), physical vapor deposition (PVD), atomic layer deposition (ALD), plasma enhanced CVD (PECVD) or other suitable techniques. In some embodiments, the dummy gate electrode layer 154 may include polycrystalline-silicon (poly-Si), poly-crystalline silicon-germanium (poly-SiGe), metallic nitrides, metallic silicides, metallic oxides, or metals. In some embodiments, the dummy gate electrode layer 154 includes a metal-containing material such as TiN, TaN, TaC, Co, Ru, Al, combinations thereof, or multi-layers thereof. The dummy gate electrode layer 154 may be deposited by CVD, physical vapor deposition (PVD), sputter deposition, or other techniques suitable for depositing conductive materials.

After formation of the dummy gate structure 150 is completed, gate spacers 160 (see FIG. 2A) and fin spacers 162 (see FIG. 2B) are formed on sidewalls of the dummy gate structure 150 as shown in FIG. 2A and on sidewalls of the fin structure 125 as shown in FIG. 2B. For example, a spacer material layer is deposited on the substrate 110. The spacer material layer may be a conformal layer that is subsequently etched back to form gate sidewall spacers. In the illustrated embodiment, a spacer material layer is disposed conformally on top and sidewalls of the dummy gate structure 150 and the fin structure 125. The spacer material layer may include a dielectric material such as silicon oxide, silicon nitride, silicon carbide, silicon oxynitride, SiCN films, silicon oxycarbide, SiOCN films, and/or combinations thereof. In some embodiments, the spacer material layer includes multiple layers, such as a first spacer layer and a second spacer layer formed over the first spacer layer. By way of example, the spacer material layer may be formed by depositing a dielectric material over the dummy gate structure 150 and the fin structure 125 using suitable deposition processes. An anisotropic etching process is then performed on the deposited spacer material layer to expose portions of the fin structure 125 not covered by the dummy gate structure 150 (e.g., over the source/drain regions of the fin structure 125). Portions of the spacer material layer directly above the dummy gate structure 150 and the fin structure 125 may be completely removed by this anisotropic etching process. Portions of the spacer material layer on sidewalls of the dummy gate structure 150 and the fin structure 125 may remain, forming gate sidewall spacers, which are denoted as the gate spacers 160 and the fin spacers 162, for the sake of simplicity. As shown in FIG. 2B, the process conditions (e.g., tilted angle of directional plasma ion beams used in a plasma etching process) for patterning the spacer material layer are controlled, so that top ends of the fin spacers 162 are lower than the top surface of the fin structure 125. In this way, the top surface and upper portions of sidewalls of the fin structure 125 are exposed. A portion of the spacer material layer may remain on the isolation structures 140 and connects neighboring fin spacers 162. In some embodiments, the dummy gate structure 150 can be interchangeably referred to a dummy gate, a dummy gate pattern, a dummy gate strip, an isolation structure, or a dielectric gate.

Reference is made to FIGS. 3A and 3B. Exposed portions of the fin structure 125 that extend laterally beyond the gate spacers 160 (e.g., in source/drain regions S/D of the fin structure 125) are etched by using, for example, an anisotropic etching process that uses the dummy gate structure 150 and the gate spacers 160 as an etch mask, resulting in recesses R1 into the fin structure 125. After the anisotropic etching, end surfaces of the epitaxial layers 122a, 122b, 122m, and the epitaxial layers 124a, 124b and respective outermost sidewalls of the gate spacers 160 are substantially coterminous, due to the anisotropic etching. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

Subsequently, the epitaxial layers 122a, 122b, and 122m are laterally or horizontally recessed by using suitable etch techniques, resulting in lateral recesses R2 and a space S1 each vertically between corresponding epitaxial layers 124a and 124b. This operation may be performed by using a selective etching process. By way of example and not limitation, the epitaxial layers 122a, 122b, and 122m are SiGe and the epitaxial layers 124a and 124b are silicon allowing for the selective etching of the epitaxial layers 122a, 122b, and 122m. In some embodiments, the selective dry etching etches SiGe at a faster etch rate than it etches Si. As a result, the epitaxial layers 124a and 124b laterally extend past opposite end surfaces of the epitaxial layers 122a, 122b. In addition, since the epitaxial layer 122m (see FIG. 2A) has a greater germanium atomic concentration than the epitaxial layers 122a and 122b, the selective dry etching etches the epitaxial layer 122m at a faster etch rate than it etches the epitaxial layers 122a, 122b, and thus the epitaxial layer 122m can be completely removed while the epitaxial layers 122a, 122b can be only partially removed.

Subsequently, inner dielectric spacers 172 and 174 are filled in the recesses R2 and the space S1 (see FIG. 3A), respectively. For example, spacer material layers are formed to fill the recesses R2 and the space S1 left by the lateral etching of the epitaxial layers 122a, 122b, and 122m discussed above. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes.

After the deposition of the spacer material layer, an anisotropic etching process may be performed to trim the deposited spacer material layer, such that portions of the deposited spacer material layer that fill the recesses R2 and the space S1 left by the lateral etching of the epitaxial layers 122a, 122b, and 122m are left. After the trimming process, the remaining portions of the deposited spacer material are denoted as inner dielectric spacers 172 in the recesses R2 and the inner dielectric spacers 174 in the recesses S1, for the sake of simplicity. The inner dielectric spacers 172 and 174 serve to isolate metal gates from source/drain epitaxial structures formed in subsequent processing.

Reference is made to FIGS. 4A and 4B. First source/drain epitaxial structures 180 are formed over the source/drain regions S/D of the fin structure 125 and connected to the epitaxial layers 124a. In some embodiments, each of the first source/drain epitaxial structures 180 has facets 181′ facing upwardly. In some embodiments, the facets 181′ are {111} facets. The first source/drain epitaxial structures 180 may be formed by performing an epitaxial growth process that provides an epitaxial material on the fin structure 125. In some embodiments, the first source/drain epitaxial structures 180 may include Ge. Si, GaAs, AlGaAs, SiGe, GaAsP, SiP, or other suitable material. The first source/drain epitaxial structures 180 may be doped by introducing doping species including: p-type dopants, such as boron or BF₂; n-type dopants, such as phosphorus or arsenic; and/or other suitable dopants including combinations thereof. In some exemplary embodiments, the first source/drain epitaxial structures 180 in a p-type include SiGeB and/or GeSnB. In some embodiments, the first source/drain epitaxial structure 180 can be interchangeably referred to as a source/drain pattern or an epitaxial pattern.

An interlayer dielectric (ILD) layer 194 is formed over the substrate 110. In some embodiments, a contact etch stop layer (CESL) 192 is also formed prior to forming the ILD layer 194. In some examples, the CESL 192 includes a silicon nitride layer, silicon oxide layer, a silicon oxynitride layer, and/or other suitable materials having a different etch selectivity than the ILD layer 194. In some embodiments, the CESL 192 and the ILD layer 194 can be collectively referred to as an isolation structure 190. In some embodiments, the ILD layer 194 includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 192. Subsequently, the isolation structures 190 are recessed, such that the upper portions of the recesses R1 may reappear.

Second source/drain epitaxial structures 185 are formed over the epitaxial isolation structure 190. In some embodiments, the second source/drain epitaxial structures 185 may include Ge, Si, GaAs, AlGaAs, SiGe, GaAsP. SiP, or other suitable material. The second source/drain epitaxial structures 185 may be doped by introducing doping species including: p-type dopants, such as boron or BF₂; n-type dopants, such as phosphorus or arsenic; and/or other suitable dopants including combinations thereof. In some exemplary embodiments, the second source/drain epitaxial structures 185 in an n-type transistor include SiP. The first source/drain epitaxial structures 180 and the second source/drain epitaxial structures 185 are made of different materials. For example, the first source/drain epitaxial structures 180 are made of SiGeB and the second source/drain epitaxial structures 185 are made of SiP. In some embodiments, the second source/drain epitaxial structure 185 can be interchangeably referred to as a source/drain pattern or an epitaxial pattern. Each of the epitaxial isolation stacks 190 is between one of the first source/drain epitaxial structures 180 and one of the second source/drain epitaxial structures 185 to electrically isolate the first source/drain epitaxial structure 180 from the second source/drain epitaxial structure 185.

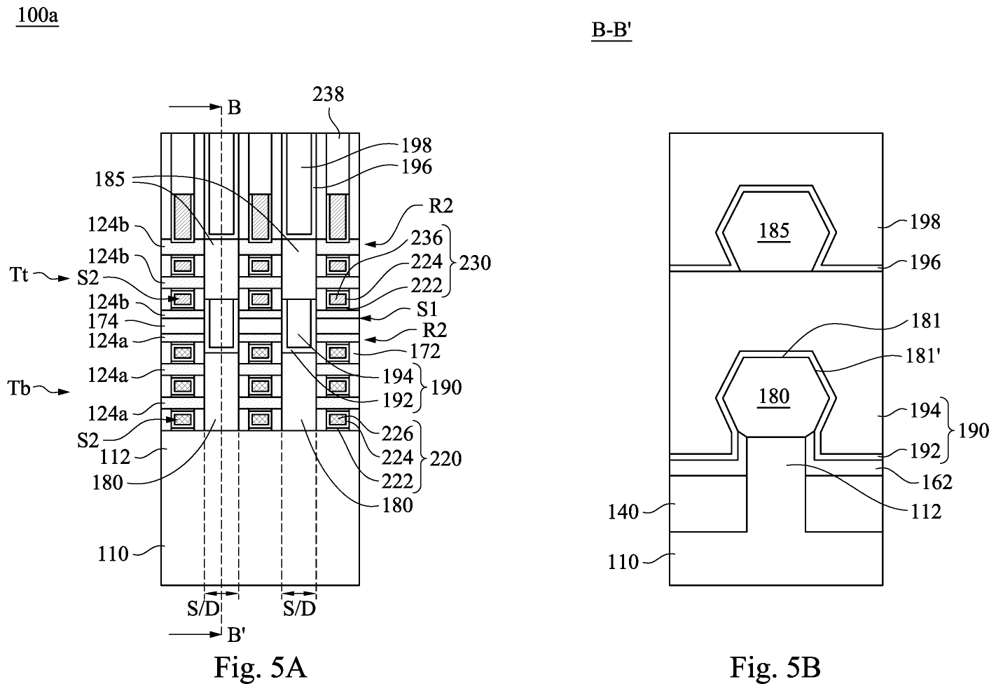

Reference is made to FIGS. 5A and 5B. An ILD layer 198 is formed over the substrate 110. In some embodiments, a CESL 196 is also formed prior to forming the ILD layer 198. In some examples, the CESL 196 includes a silicon nitride layer, silicon oxide layer, a silicon oxynitride layer, and/or other suitable materials having a different etch selectivity than the ILD layer 198. In some embodiments, the CESLs 192, 196 and the ILD layers 194, 198 can be collectively referred to as a dielectric structure. In some embodiments, the ILD layer 198 includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL. After depositing the CESL 196 and the ILD layer 198, a planarization process (e.g., CMP process) may be performed to remove excessive materials of the CESL 196 and the ILD layer 198 overlying the dummy gate structures 150 and further removes hard mask layers 156 and 158 (as shown in FIGS. 4A and 4B), such that the dummy gate electrode layer 154 is exposed.

Subsequently, the dummy gate dielectric layer 152 and/or the dummy gate electrode layer 154 is removed, thus resulting in a gate trench GT between the gate spacers 160, with the epitaxial layers 122a and 122b exposed in the gate trench GT. Subsequently, the epitaxial layers 122a and 122b in the gate trench GT are removed, thus forming spaces S2 between neighboring epitaxial layers (i.e., channel layers) 124a and 124b. In some embodiments, the epitaxial layers 124a and 124b can be interchangeably referred to as nanostructure (nanowires, nanoslabs and nanorings, nanosheet, etc., depending on their geometry).

A (metal) gate structure 220 is formed in the gate trench GT and the spaces S2 to surround each of the epitaxial layers 124a and 124b suspended in the gate trench GT and the spaces S2. In various embodiments, the gate structure 220 includes interfacial layers 222 formed around the respective epitaxial layers 124a and 124b, a high-k gate dielectric layer 224 formed on the interfacial layers 222, and a gate electrode layer 226 formed around the high-k gate dielectric layer 224 and filling a remainder of gate trench GT. In some embodiments, the interfacial layers 222 may include a dielectric material such as silicon oxide (SiO₂), HfSiO, or silicon oxynitride (SiON). The high-k dielectric layer 224 may include dielectric materials having a high dielectric constant (high-k), for example, greater than that of thermal silicon oxide (˜3.9). For example, the high-k dielectric layer 224 may include hafnium oxide (HfO₂). The gate electrode layer 226 may include a work function metal layer and/or a fill metal formed around the work function metal layer. For an n-type FinFET, the work function metal layer 224 may include one or more n-type work function metals. On the other hand, for a p-type FinFET, the work function metal layer 224 may include one or more p-type work function metals. In some embodiments, the fill metal may exemplarily include, but are not limited to, tungsten, aluminum, copper, nickel, cobalt, titanium, tantalum, titanium nitride, tantalum nitride, nickel silicide, cobalt silicide, TaC. TaSiN, TaCN, TiAl, TiAlN, or other suitable materials. After the formation of the gate structure 220, the gate electrode layer 226 is etched back by using an etching process, such that the upper portions of the gate trenches GT may reappear. In some embodiments, the gate structure 220 can be interchangeably referred to a metal gate, a gate pattern, or a gate strip.

A gate electrode layer 236 is deposited in the gate trench GT and over the gate electrode layer 226. Therefore, a gate structure 230 including the gate dielectric layer 222, the work function metal layer 224, and the fill metal 236 is formed within the remainder of the spaces S2. As such, the semiconductor device 100a is formed. In some embodiments, the gate structure 230 can be interchangeably referred to a metal gate, a gate pattern, or a gate strip. In some embodiments, the gate electrode layer 236 may include a work function metal layer and/or a fill metal formed around the work function metal layer. For an n-type FinFET, the work function metal layer 234 may include one or more n-type work function metals. On the other hand, for a p-type FinFET, the work function metal layer 234 may include one or more p-type work function metals. In some embodiments, the fill metal may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

The semiconductor device 100a includes a bottom-tier transistor Tb and a top-tier transistor Tt. The top-tier transistor Tt is over the bottom-tier transistor Tb. The bottom-tier transistor Tb includes the channel layers 124a, the first source/drain epitaxial structures 180 on opposite sides of the channel layers 124a and connected to the channel layers 124a, and the gate structure 220 wrapping around the channel layers 124a. The top-tier transistor Tt includes the channel layers 124b, the second source/drain epitaxial structures 185 on opposite sides of the channel layers 124b and connected to the channel layers 124b, and a (metal) gate structure 230 wrapping around the channel layers 124b. In some embodiments, the bottom-tier transistor Tb is a p-type transistor, and the top-tier transistor Tt is an n-type transistor. In some other embodiments, the bottom-tier transistor Tb is an n-type transistor, and the top-tier transistor Tt is a p-type transistor. Subsequently, a hard mask layer 238 is formed over the gate structure 230. In some embodiments, the hard mask layer 238 may be made of a nitride-based material, such as Si₃N₄, SiON, or a carbon-based material, such as SiC, SiOC, SiOCN, or combinations thereof.

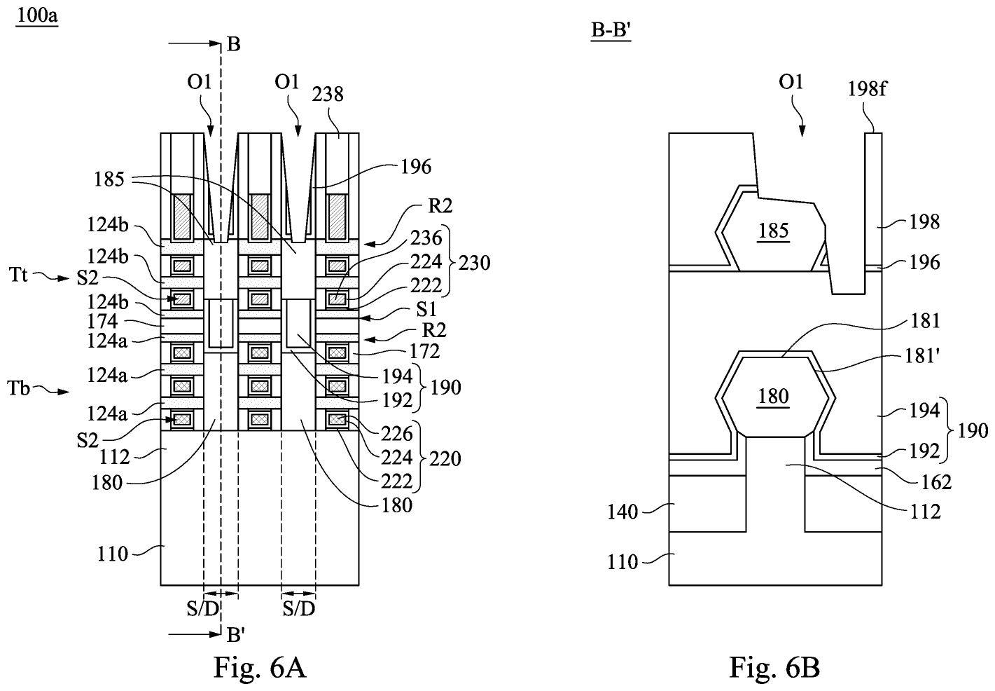

Reference is made to FIGS. 6A and 6B. A source/drain contact opening O1 is formed through the CESL 196 and the ILD layer 198 to expose the second source/drain epitaxial structure 185 from a front-side 198f of the ILD layer 198. Specifically, one or more etching process may be performed to sequentially etch through the CESL 196 and the ILD layer 198 down to the second source/drain epitaxial structure 185 to form a source/drain contact opening O1. In some embodiments, the etching process would consume the second source/drain epitaxial structure 185, and thus the second source/drain epitaxial structure 185 may be damaged as shown in FIGS. 6A and 6B. That is, the first source/drain epitaxial structure 180 may have an asymmetrical cross sectional view. In some embodiments, the source/drain contact opening O1 may further downwardly extend to the ILD layer 194 as shown in FIG. 6B.

In some embodiments, the etching process is an anisotropic dry etching process (e.g., a reactive-ion etching (RIE) process or an atomic layer etching (ALE) process). By way of example and not limitation, a dry etching process may implement an oxygen-containing gas, a fluorine-containing gas (e.g., CF₄, SF₆, CH₂F₂, CHF₃, CH₃F and/or C₄F₈), a chlorine-containing gas (e.g., Cl₂ and/or BCl₃), a bromine-containing gas (e.g., HBr), an iodine-containing gas, other suitable gases and/or plasmas, and/or combinations thereof.

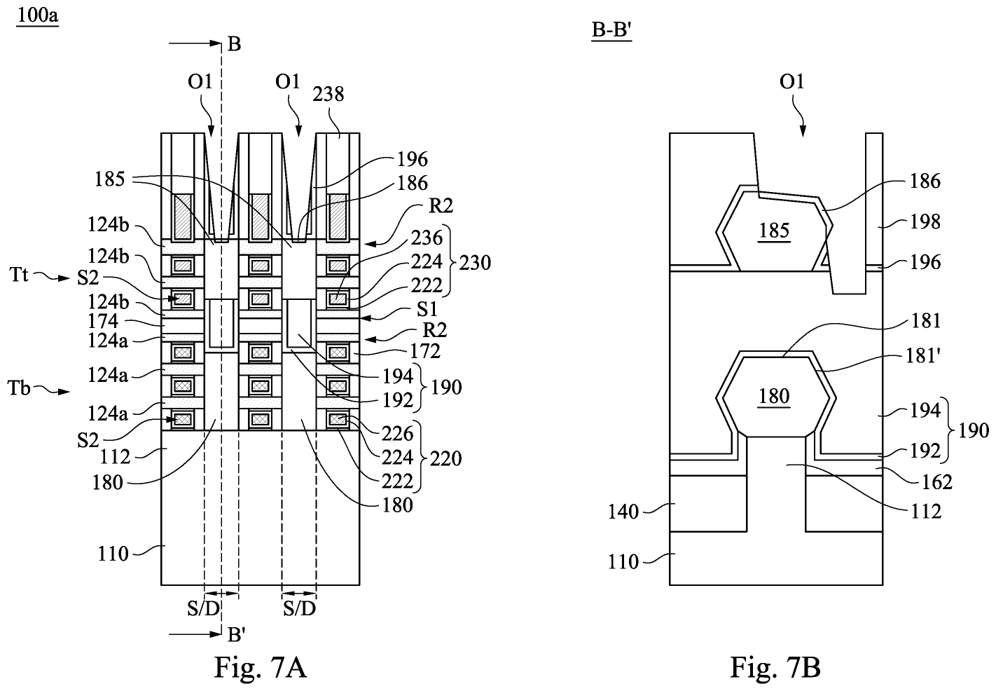

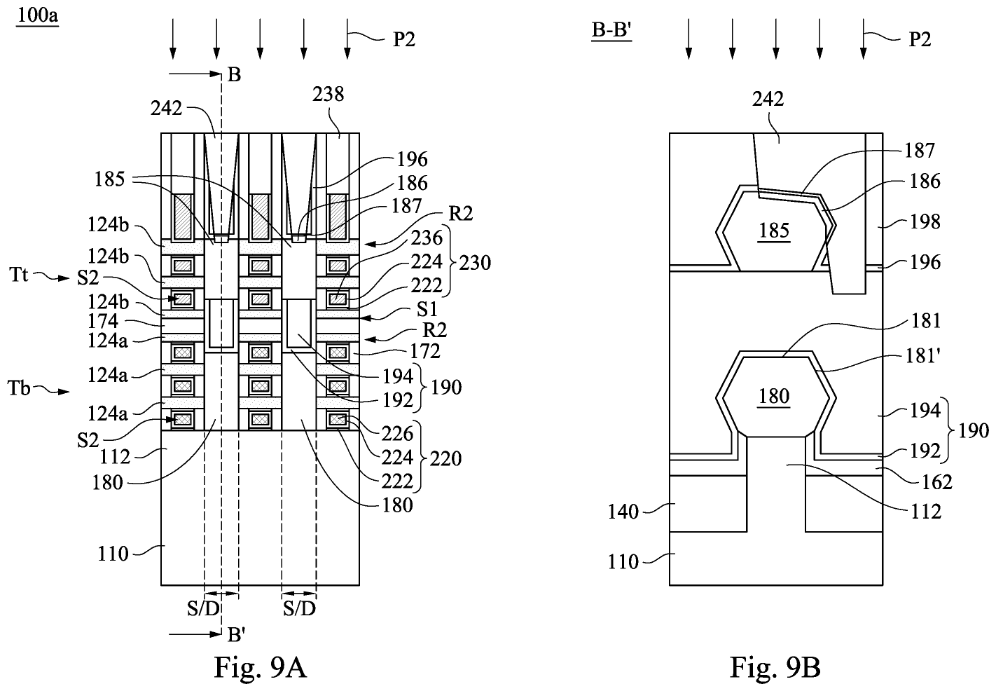

Reference is made to FIGS. 7A and 7B. Before the source/drain contact 242 (see FIGS. 9A and 9B) is formed, a metal silicide layer 186 may be selectively formed on the second source/drain epitaxial structure 185 by a metal silicidation process. In some embodiments, the metal silicide layer 186 may be formed to wrap-around the second source/drain epitaxial structure 185, and the formation thereof can be referred to as a silicide-first approach with thermal stable silicide which can endure potential HK/MG thermal process (>850° C.). The metal silicidation process is to make a reaction between metal and silicon (or polycrystalline silicon). Regarding the metal silicidation process, a first rapid thermal annealing (RTA) process may be performed in, for example, Ar, He, N2 or other inert atmosphere at a first temperature, such as lower than 200˜300° C., to convert the deposited metal layer into metal silicide. This is followed by an etching process to remove the unreacted metal layer from the metal silicide. The etching process may include a wet etch, a dry etch, and/or a combination thereof. As an example, the etchant of the wet etching may include a mixed solution of H₂SO₄, H₂O₂, H₂O, and/or other suitable wet etching solutions, and/or combinations thereof. Then, a second annealing or RTA step at a second temperature higher than the first temperature, such as 400˜500° C., thereby forming the metal silicide layer 186 with low resistance. In some embodiments, the metal silicide layer 186 formed over the second source/drain epitaxial structure 185 can be interchangeably referred to an n-silicide when the second source/drain epitaxial structure 185 is an n-type source/drain region. In some embodiments, the metal silicide layer 186 may include titanium silicide (TiSi), nickel silicide (NiSi), cobalt silicide (CoSi), Ni—Pt, or combinations thereof. The metal silicide layer 186 formed on the second source/drain epitaxial structure 185 can provide a planar silicide surface area without compromising Rcsd. In some embodiments, the metal silicide layer 186 can be interchangeably referred to as a front-side metal silicide layer.

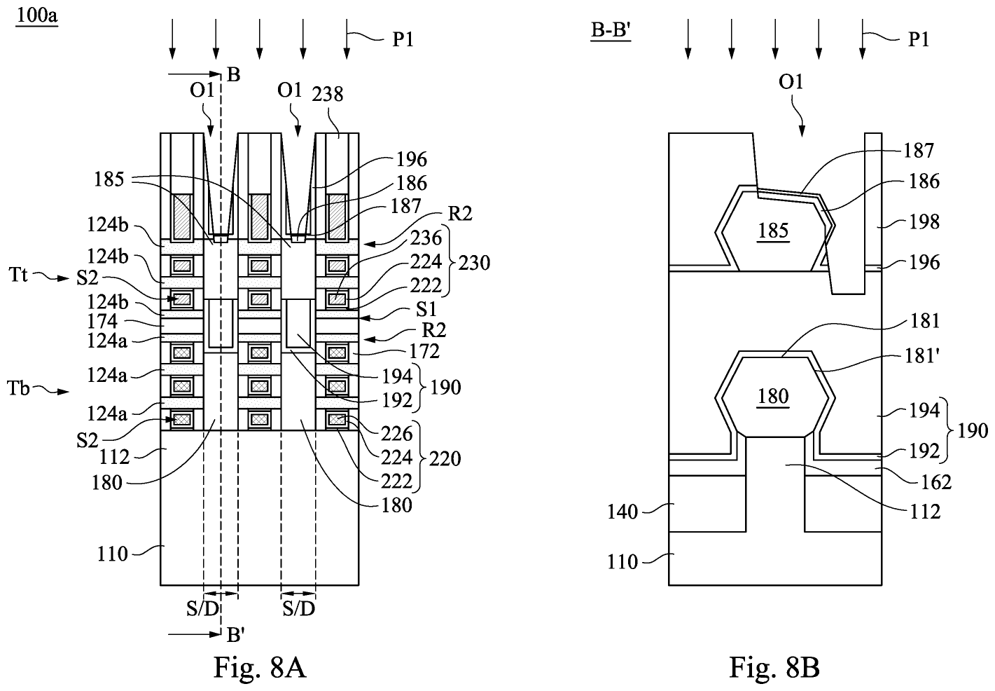

Reference is made to FIGS. 8A and 8B. A metal cap 187 formed atop the metal silicide layer 186 by suitable process, such as CVD or ALD. In some embodiments, the metal cap 187 is formed on the metal silicide layer 186 using a deposition process P1, such as bottom-up approach. For example, the metal cap 187 is selectively grown on the metal surface, such as the metal silicide layer 186, and thus the ILD layers 194 and 198 are substantially free from the growth of the metal cap 187. Because the metal silicide layer 186 and the metal cap 187 can be selectively formed on the second source/drain epitaxial structure 185 other than the surrounding dielectric, the metal silicide layer 186 and the metal cap 187 can occupy less space in the source/drain opening O1, which in turn facilitates the following metal (e.g. source/drain contact 242 as shown in FIGS. 9A and 9B) filling in the source/drain opening O1, and thus the silicide-diffusion contact resistance of the IC structure can be improved.

The metal cap 187 may be, by way of example and not limitation, substantially fluorine-free tungsten (FFW) films having an amount of fluorine contaminants less than 5 atomic percent. The FFW films or the FFW-comprising films may be formed by ALD or CVD using one or more non-fluorine based tungsten precursors such as, but not limited to, tungsten pentachloride (WCl₅), tungsten hexachloride (WCl₆). In some embodiments, the metal cap 187 may have a chlorine atomic concentration in a range from about 0.1 to about 5%, and thus a distinguishable interface may be formed between the metal cap 187 and the source/drain contact 242 (see FIGS. 9A and 9B). In some embodiments, portions of the metal cap 187 may overflow over the metal silicide layer 186, such that the metal caps 187 may also cover the exposed surface of the ESL 196. Since the metal cap 187 is formed in a bottom-up manner, the formation thereof may be simplified by, for example, reducing repeated etching back processes which are used to remove unwanted metal materials resulting from conformal growth. In some embodiments, the metal cap 187 can be interchangeably referred to as a front-side metal cap 187.

The selective formation of the metal cap 187 on the metal silicide layer 186, rather than on the dielectric layers (e.g., ILD layers 194 and 198), is primarily due to the contrasting electrical behaviors exhibited by the metal silicide and the dielectric materials. The deposition process P1 leverages this difference to achieve targeted growth of the metal cap 187 solely on the metal silicide layer 186. Electric behaviors of a material are governed by the nature of chemical bonding among its constituent atoms and its ability to effectively transport electric charge. In this context, the distinct electrical behaviors exhibited by the metal silicide and the dielectric materials arise from the difference in the electrical conductivity between the metal silicide layer 186 and the dielectric layers 194 and 198.

Specifically, the metal silicide layer 186 can be composed of a metal (e.g., tungsten) and a semiconductor (e.g., silicon), which form a compound with metallic properties. These compounds exhibit high electrical conductivity due to the presence of free electrons that can traverse the material with relative ease. As a result, the metal silicide layer 186 can retain electric charge and generate an electrostatic field in its vicinity. On the other hand, dielectric materials (e.g., the dielectric layers 194 and 198) are insulators with poor electric charge conduction. They exhibit very low electrical conductivity because the electrons in the material are firmly bonded to their parent atoms, restricting their mobility. This characteristic hinders dielectric layers' ability to maintain an electric charge and create an electrostatic field.

In the deposition process using tungsten precursors such as tungsten pentachloride (WCl₅) or tungsten hexachloride (WCl₆), the tungsten atoms are surrounded by negatively charged chloride ions. Due to the higher electrical conductivity of the metal silicide layer 186, it can accumulate a net positive charge that attracts the negatively charged chloride ions, thereby facilitating the absorption of tungsten atoms onto the metal silicide layer. In contrast, the dielectric layers 194 and 198 cannot hold a significant charge due to their insulating nature, rendering the absorption of tungsten atoms onto their surface less likely. Consequently, the metal cap 187 is selectively formed on the metal silicide layer 186, not on the dielectric layers.

Reference is made to FIGS. 9A and 9B. A source/drain contact 242 is formed in a remainder of the source/drain contact opening O1 and on the metal cap 187. In some embodiments, the source/drain contact 242 can be interchangeably referred to as a metal-like defined (MD) layer. In some embodiments, the source/drain contact 242 can be interchangeably referred to as a front-side contact. In greater detail, a conductive material may be formed by using a metallization process as well as the use of a deposition process P2 different than the deposition process P1 to fill the source/drain contact opening O1. By way of example and not limitation, the deposition process P1 of forming the metal cap 187 may be a chemical vapor deposition (CVD) process, and the deposition process P2 of forming the source/drain contact 242 may be a physical vapor deposition (PVD) process. Subsequently, the excess portions of the conductive layer are removed, either through etching, chemical mechanical polishing (CMP), or the like, forming the upper surface of the metal-filled opening substantially coplanar with a top surface of the ILD layer 198. The remaining portions of the conductive material in the source/drain contact opening O1 forms the source/drain contact 242. The conductive material may include a low resistivity conductor material selected from the group of conductor materials including, but not limited to, tungsten and tungsten-based alloy. Alternatively, the conductive material may include various materials, such as cobalt, copper, ruthenium, aluminum, gold, silver, another suitable conductive material, or combinations thereof. In some embodiments, the conductive material may be a tungsten-containing layer formed over a tungsten seed layer (e.g., tungsten cap formed on the second source/drain epitaxial structure 185). In some embodiments, the source/drain contact 242 has a first cross-sectional profile and a second cross-sectional profile between the first cross-sectional profile and the metal cap 187 and having a wider width than the second cross-sectional profile.

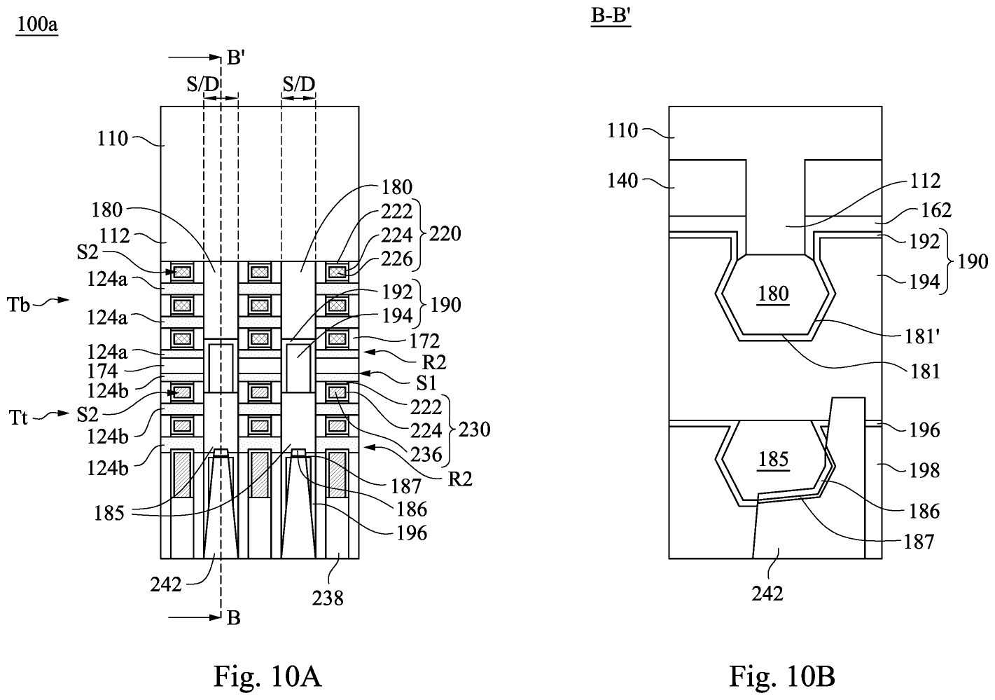

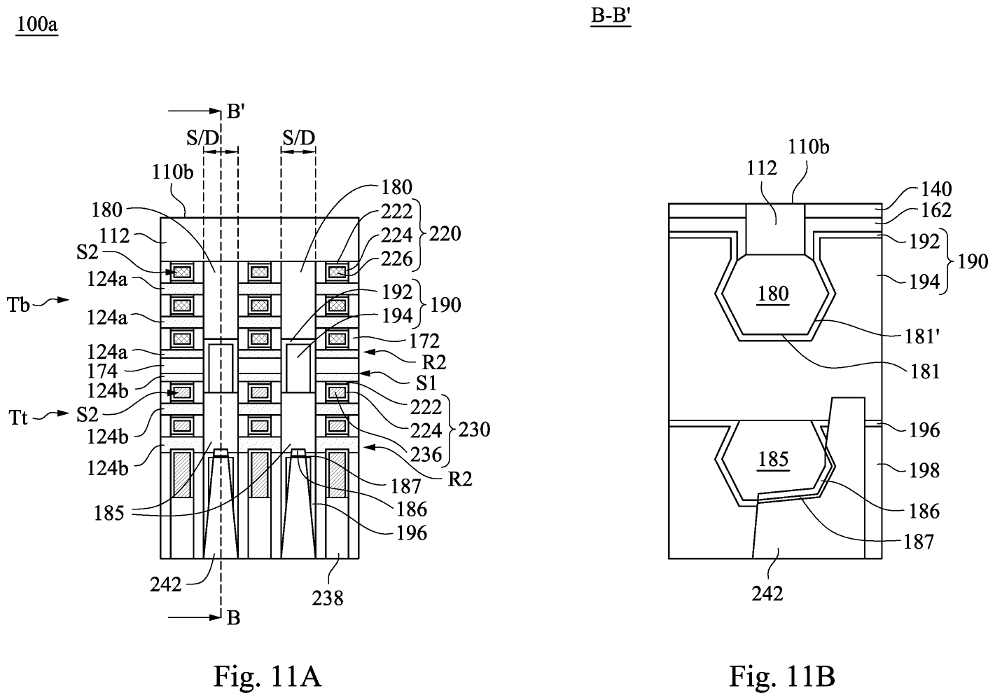

Reference is made to FIGS. 10A-11B. The structures of FIGS. 9A and 9B are “flipped” upside down (see FIGS. 10A and 10B), and the substrate 110 can be thinned from the back-side 110b thereof (see FIGS. 11A and 11B). The substrate 110 can be thinned in a plurality of process operations, for example, CMP, HNA, and/or TMAH etching from the back-side 110b of the substrate 110.

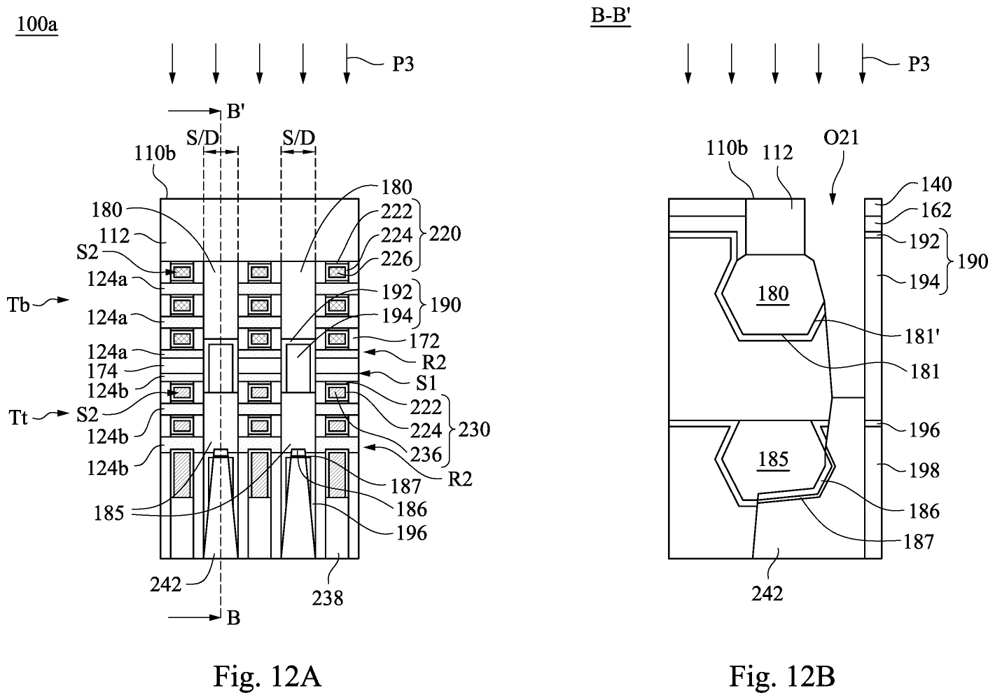

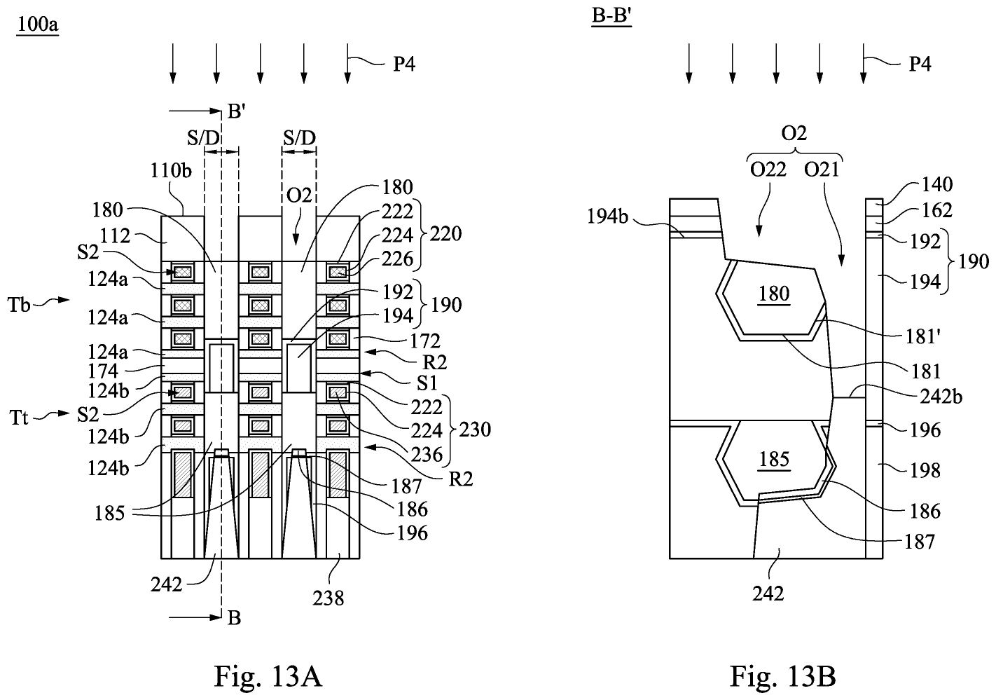

Reference is made to FIGS. 12A-13B. A source/drain contact opening O2 (see FIGS. 13A and 13B) is formed through the ILD layer 194 to expose the first source/drain epitaxial structure 180 as well as the source/drain contact 242.

As shown FIGS. 12A and 12B, one or more etching process P3 may be performed to sequentially etch through the isolation structures 140, the fin spacers 162, the CESL 192, and the ILD layer 194 from a back-side 194b of the ILD layer 194 down to the source/drain contact 242 to form a subsidiary contact opening O21, and the facets 181′ of the first source/drain epitaxial structure 180 are also exposed from the subsidiary contact opening O21. In some embodiments, the etching process is performed until a back-side surface 242b of the source/drain contact 242 is exposed, and the source/drain contact 242 can act as an etch stop layer of the etching process. In some embodiments, the etching process would consume the first source/drain epitaxial structure 180, and thus the first source/drain epitaxial structure 180 may be damaged as shown in FIGS. 12A and 12B. That is, the second source/drain epitaxial structure 185 may have an asymmetrical cross sectional view. In some embodiments, the etching process is an anisotropic dry etching process (e.g., a reactive-ion etching (RIE) process or an atomic layer etching (ALE) process). By way of example and not limitation, a dry etching process may implement an oxygen-containing gas, a fluorine-containing gas (e.g., CF₄, SF₆, CH₂F₂. CHF₃, CH₃F and/or C₄F₈), a chlorine-containing gas (e.g., Cl₂ and/or BC₃), a bromine-containing gas (e.g., HBr), an iodine-containing gas, other suitable gases and/or plasmas, and/or combinations thereof.

Subsequently, as shown in FIGS. 13A and 13B, the protruding portion 112 is removed to expose the first source/drain epitaxial structure 180. An etching process P4 can be performed to remove the protruding portion 112 on the first source/drain epitaxial structure 180 to form a subsidiary contact opening O22 (see FIG. 13B), in which the first source/drain epitaxial structure 180 can act as an etch stop layer, such that the subsidiary contact opening O22 can inherit the shape of the protruding portion 112 and self-align with the first source/drain epitaxial structure 180. In some embodiments, the subsidiary contact openings O21 and O22 can be collectively referred to as the source/drain contact opening O2. In some embodiments, the etching process P4 may be an anisotropic dry etch process, such as a dry etch process (e.g., RIE, a NBE, or the like) and may employ a different etchant than that used in the etching process P3. In some embodiments, the protruding portion 112 may be made of a material that has a high etching selectivity relative to the source/drain regions 218a, STI structure 251, and the gate spacer 233. For example, the etching selectivity, which is the ratio of the etching rate of the dielectric layer 249 to the first source/drain epitaxial structure 180, the fin spacers 162, the CESL 192, and the ILD layer 194 when the protruding portion 112 is etched.

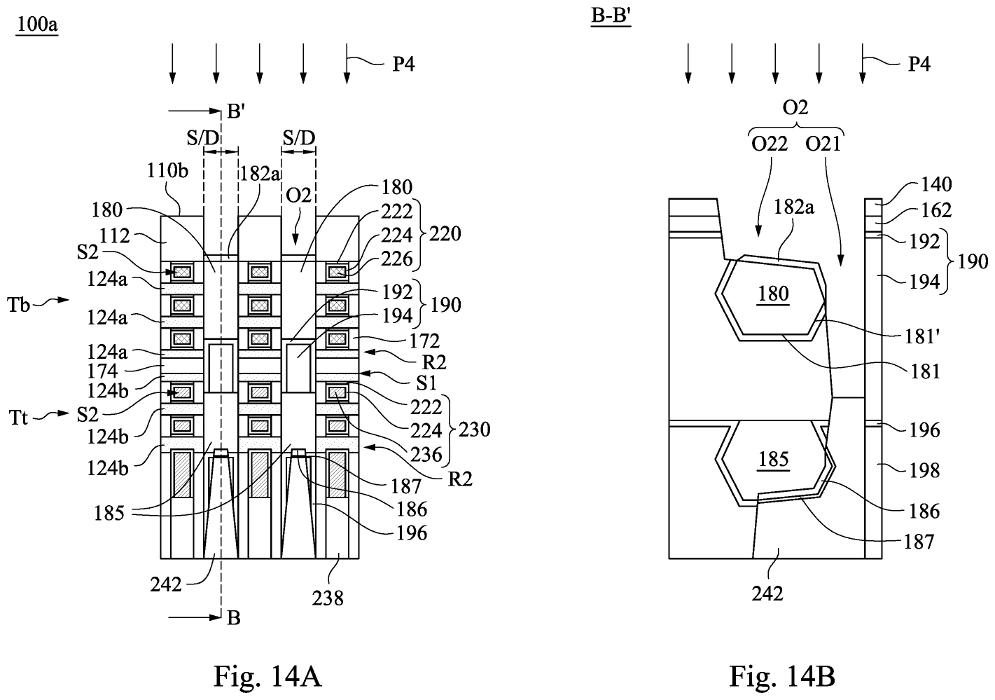

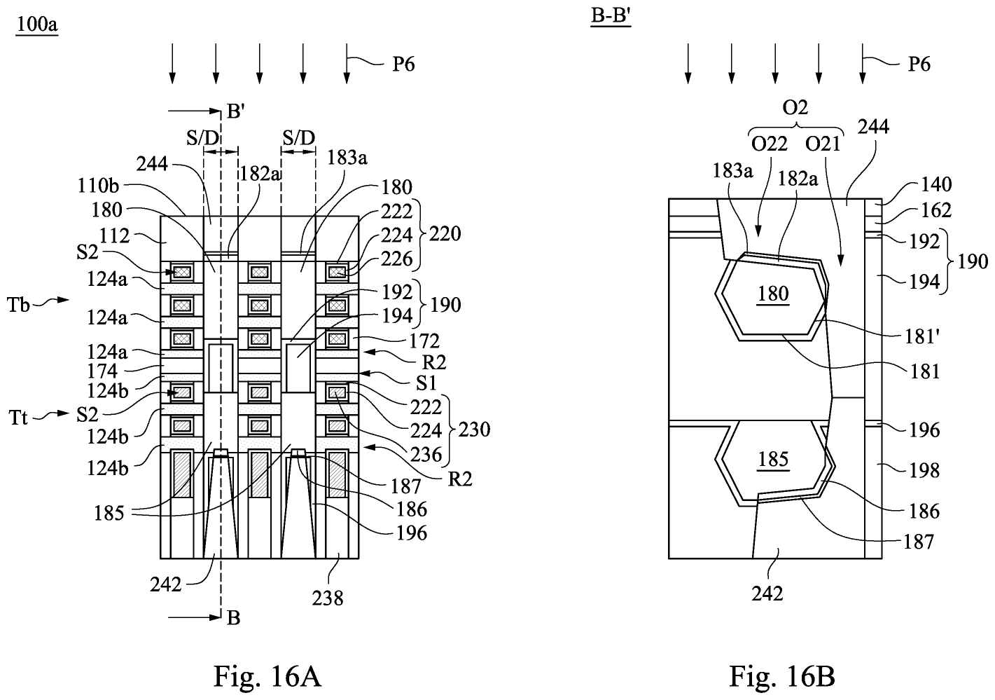

Reference is made to FIGS. 14A and 14B. Before the source/drain contact 244 (see FIGS. 16A and 16B) is formed, a metal silicide layer 182a may be selectively formed on the first source/drain epitaxial structure 180 by a metal silicidation process. In some embodiments, the metal silicide layer 182a may be formed to wrap-around the first source/drain epitaxial structure 180, and the formation thereof can be referred to as a silicide-first approach with thermal stable silicide which can endure potential HK/MG thermal process (>850° C.). The metal silicidation process is to make a reaction between metal and silicon (or polycrystalline silicon). Regarding the metal silicidation process, a first rapid thermal annealing (RTA) process may be performed in, for example, Ar, He, N2 or other inert atmosphere at a first temperature, such as lower than 200˜300° C., to convert the deposited metal layer into metal silicide. This is followed by an etching process to remove the unreacted metal layer from the metal silicide. The etching process may include a wet etch, a dry etch, and/or a combination thereof. As an example, the etchant of the wet etching may include a mixed solution of H₂SO₄, H₂O₂, H₂O, and/or other suitable wet etching solutions, and/or combinations thereof. Then, a second annealing or RTA step at a second temperature higher than the first temperature, such as 400˜500° C., thereby forming the metal silicide layer 182a with low resistance. In some embodiments, the metal silicide layer 182a formed over the first source/drain epitaxial structure 180 can be interchangeably referred to a p-silicide when the first source/drain epitaxial structure 180 is a p-type source/drain region. In some embodiments, the metal silicide layer 182a may include molybdenum silicon germanium (MoSiGe), titanium silicide (TiSi), nickel silicide (NiSi), cobalt silicide (CoSi), Ni—Pt, or combinations thereof. The metal silicide layer 182a formed on the first source/drain epitaxial structure 180 can provide a planar silicide surface area without compromising Rcsd. In some embodiments, the metal silicide layer 182a can be interchangeably referred to as a back-side metal silicide layer. In some embodiments, the metal silicide layer 182a on the first source/drain epitaxial structure 180 may be made of a different material than the metal silicide layer 186 on the second source/drain epitaxial structure 185, and thus the formation of the metal silicide layers 182a and 186 can be referred to as a dual silicide for low Rcsd on different device types, e.g., n-type, p-type devices. By way of example and not limitation, the metal silicide layer 182a can be made of MoSiGe, and the metal silicide layer 186 can be made of TiSi.

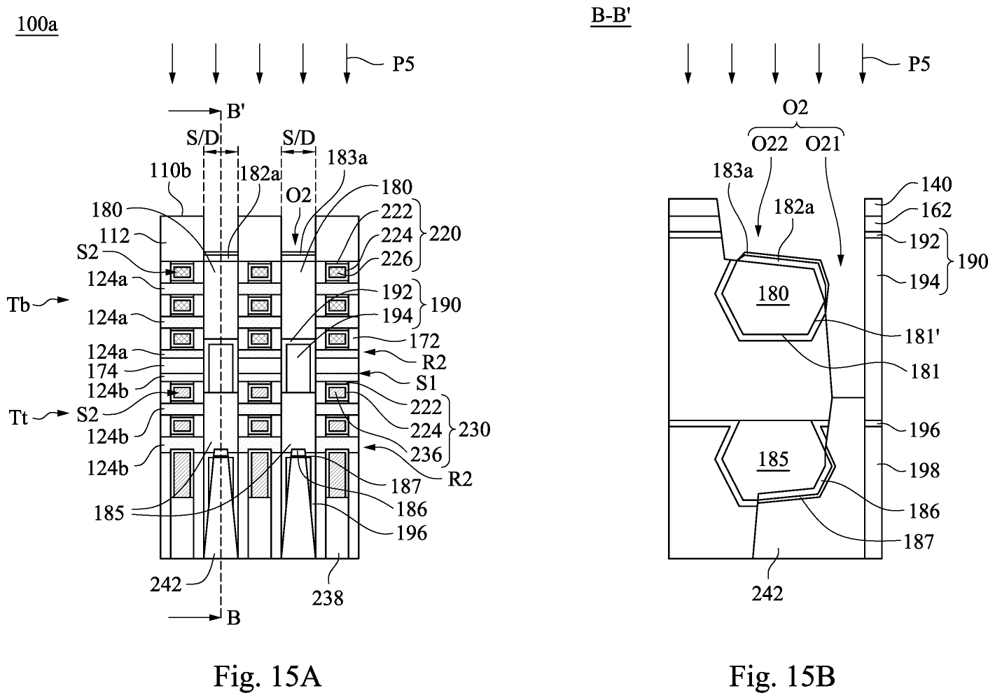

Reference is made to FIGS. 15A and 15B. A metal cap 183a formed atop the metal silicide layer 182a by suitable process, such as CVD or ALD. In some embodiments, the metal cap 183a is formed on the metal silicide layer 182a using a deposition process P5, such as bottom-up approach. For example, the metal cap 183a is selectively grown on the metal surface, such as the metal silicide layer 182a, and thus the ILD layer 194 is substantially free from the growth of the metal cap 183a. Because the metal silicide layer 182a and the metal cap 183a can be selectively formed on the first source/drain epitaxial structure 180 other than the surrounding dielectric, the metal silicide layer 182a and the metal cap 183a can occupy less space in the source/drain opening O2, which in turn facilitates the following metal (e.g. source/drain contact 244 as shown in FIGS. 16A and 16B) filling in the source/drain opening O2, and thus the silicide-diffusion contact resistance of the IC structure can be improved.

The selective formation of the metal cap 183a on the metal silicide layer 182a, rather than on the dielectric layers (e.g., ILD layer 194), is primarily due to the contrasting electrical behaviors exhibited by the metal silicide and the dielectric materials. The deposition process P5 leverages this difference to achieve targeted growth of the metal cap 183a solely on the metal silicide layer 182a. Electric behaviors properties of a material are governed by the nature of the chemical bonding among its constituent atoms and its ability to effectively transport electric charge. In this context, the distinct electrical behaviors exhibited by the metal silicide and the dielectric materials arise from the difference in the electrical conductivity between the metal silicide layer 182a and the dielectric layer 194.

Specifically, the metal silicide layer 182a can be composed of a metal (e.g., tungsten) and a semiconductor (e.g., silicon), which form a compound with metallic properties. These compounds exhibit high electrical conductivity due to the presence of free electrons that can traverse the material with relative ease. As a result, the metal silicide layer 182a can retain electric charge and generate an electrostatic field in its vicinity. On the other hand, dielectric materials (e.g., the dielectric layer 194) are insulators with poor electric charge conduction. They exhibit very low electrical conductivity because the electrons in the material are firmly bonded to their parent atoms, restricting their mobiligty. This characteristic hinders dielectric layers' ability to maintain an electric charge and create an electrostatic field.

In the deposition process using tungsten precursors such as tungsten pentachloride (WCl₅) or tungsten hexachloride (WCl₆), the tungsten atoms are surrounded by negatively charged chloride ions. Due to the higher electrical conductivity of the metal silicide layer 182a, it can accumulate a net positive charge that attracts the negatively charged chloride ions, thereby facilitating the absorption of tungsten atoms onto the metal silicide layer. In contrast, the dielectric layer 194 cannot hold a significant charge due to their insulating nature, rendering the absorption of tungsten atoms onto their surface less likely. Consequently, the metal cap 183a is selectively formed on the metal silicide layer 182a, not on the dielectric layers.

The metal cap 183a may be, by way of example and not limitation, substantially fluorine-free tungsten (FFW) films having an amount of fluorine contaminants less than 5 atomic percent. The FFW films or the FFW-comprising films may be formed by ALD or CVD using one or more non-fluorine based tungsten precursors such as, but not limited to, tungsten pentachloride (WCl₅), tungsten hexachloride (WCl₆). In some embodiments, the metal cap 183a may have a chlorine atomic concentration in a range from about 0.1 to about 5%, and thus a distinguishable interface may be formed between the metal cap 183a and the source/drain contact 244 (see FIGS. 16A and 16B). In some embodiments, portions of the metal cap 183a may overflow over the metal silicide layer 182a, such that the metal caps 183 may also cover the exposed surface of the ESL 192. Since the metal cap 183a is formed in a bottom-up manner, the formation thereof may be simplified by, for example, reducing repeated etching back processes which are used to remove unwanted metal materials resulting from conformal growth. In some embodiments, the metal cap 183a can be interchangeably referred to as a back-side metal cap.

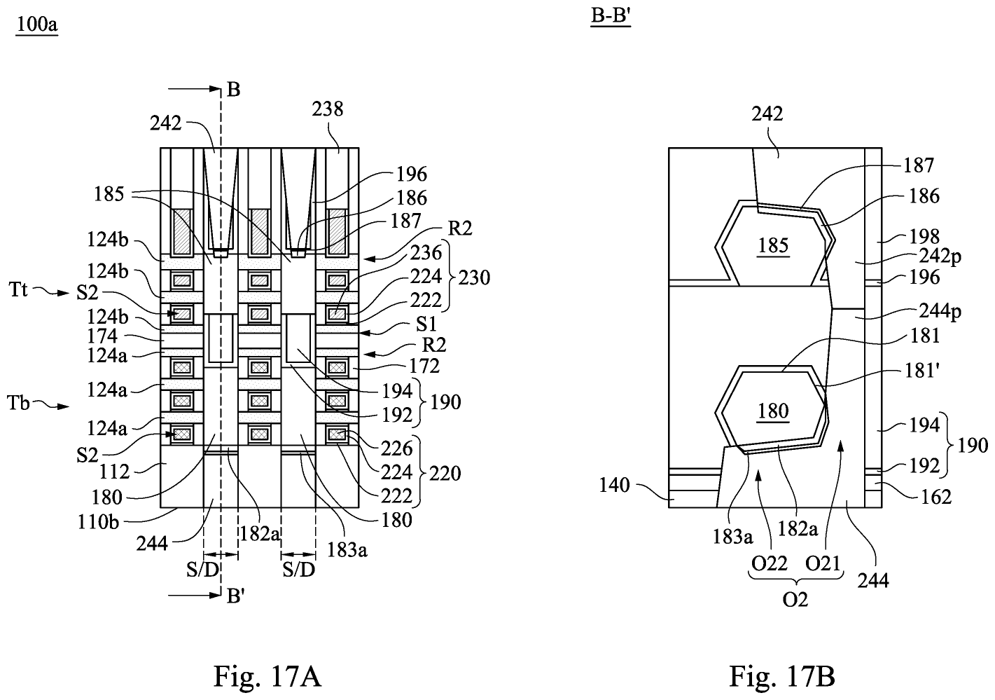

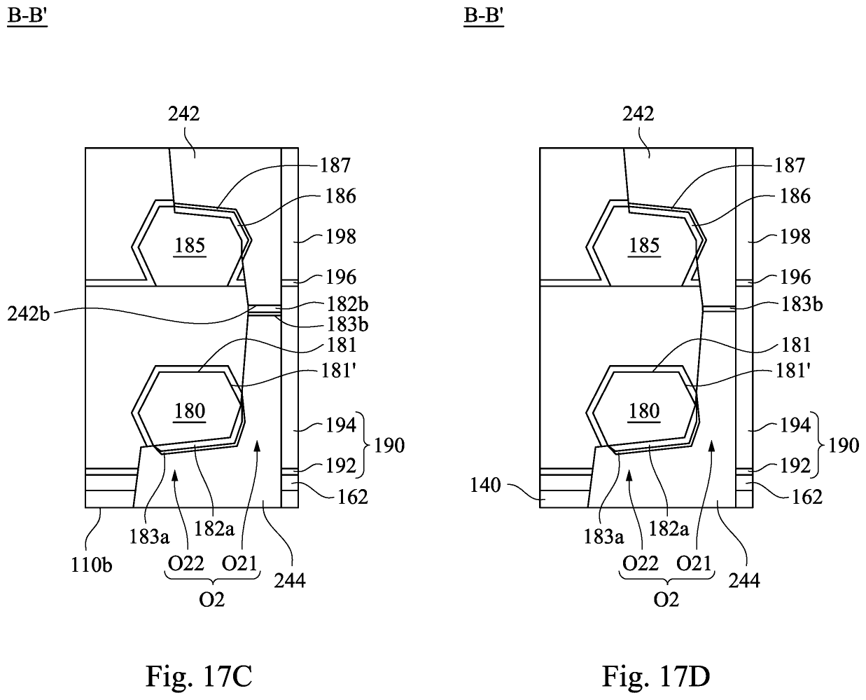

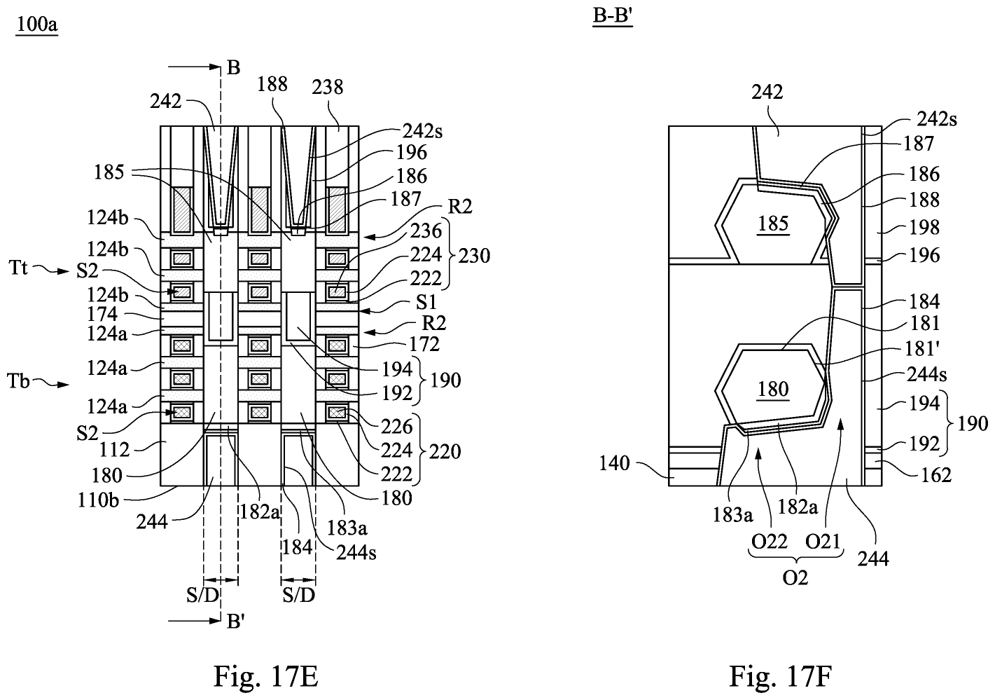

Reference is made to FIGS. 16A and 16B. A source/drain contact 244 is formed in a remainder of the source/drain contact opening O2 and on the metal cap 183a as well as the source/drain contact 242. In some embodiments, the source/drain contact 244 can be interchangeably referred to as a metal-like defined (MD) layer. In some embodiments, the source/drain contact 244 can be interchangeably referred to as a back-side contact. In greater detail, a conductive material may be formed by using a metallization process as well as the use of a deposition process P6 different than the deposition process P5 to fill the source/drain contact opening O2. By way of example and not limitation, the deposition process P5 of forming the metal cap 183a may be a chemical vapor deposition (CVD) process, and the deposition process P6 of forming the source/drain contact 244 may be a physical vapor deposition (PVD) process. Subsequently, the excess portions of the conductive layer are removed, either through etching, chemical mechanical polishing (CMP), or the like, forming the upper surface of the metal-filled opening substantially coplanar with a top surface of the ILD layer 194. The remaining portions of the conductive material in the source/drain contact opening O2 forms the source/drain contact 244. The conductive material may include a low resistivity conductor material selected from the group of conductor materials including, but not limited to, tungsten and tungsten-based alloy. Alternatively, the conductive material may include various materials, such as cobalt, copper, ruthenium, aluminum, gold, silver, another suitable conductive material, or combinations thereof. In some embodiments, the conductive material may be a tungsten-containing layer formed over a tungsten seed layer (e.g., tungsten cap formed on the second source/drain epitaxial structure 180). The structures of FIGS. 17A and 17B are “flipped” upside down of FIGS. 16A and 16B for ease of description to describe one element or feature's relationship to another element(s) or feature(s) as illustrated in the figures. In some embodiment, the back-side portion 242p of the source/drain contact 242 and the front-side portion 244p of the source/drain contacts 244 can be collectively referred to as an interconnect via. In some embodiments, because there is no metal nitride as a liner to surround the source/drain contacts 242 and 244, the source/drain contacts 242 and 244 can be directly connected by the conductive materials respectively therein, which in turn improves low Rcsd of the semiconductor device 100a. In some embodiments, the source/drain contact 244 has a first cross-sectional profile and a second cross-sectional profile between the first cross-sectional profile and the metal cap 183a and having a wider width than the second cross-sectional profile.

Reference is made to FIGS. 17C-17F. FIGS. 17C-17F illustrate schematic cross-sectional views of semiconductor structures corresponding FIGS. 17A and 17B according to some embodiments of the present disclosure. In addition, the present disclosure may repeat reference numerals and/or letters in the various examples. This repetition is for the purpose of simplicity and clarity and does not in itself dictate a relationship between the various embodiments and/or configurations discussed.

As shown in FIG. 17C, the difference between the embodiment in FIG. 17C and the embodiment in FIGS. 17A and 17B is in that an additional metal layer 182b and an additional metal cap 183b may be formed on the back-side 242b of the source/drain contact 242 and sandwiched between the source/drain contacts 242 and 244. Specifically, before the source/drain contact 244 is formed, a metal silicide layer 182a may be selectively formed on the second source/drain epitaxial structure 185 by a metal silicidation process. The deposited metal of the metal silicidation process for forming the metal silicide layer 182a may also be deposited on the back-side 242b of the source/drain contact 242, such that the metal layer 182b can be formed on the back-side 242b of the source/drain contact 242 and made of a same metal element as the metal silicide layer 182a, such as molybdenum.

The selective formation of the metal layer 182b on the back-side 242b of the source/drain contact 242, and not on the dielectric layers (e.g., ILD layer 194), can be attributed to the differences in electronic properties of the metal and the dielectric materials. The electronic properties of a material are determined by the nature of the chemical bonds between its constituent atoms and how well it conducts electric charge. In this context, the difference lies in the electrical conductivity of the source/drain contact 242 and the dielectric layer 194. The source/drain contact 242 is made of a conductive material, which exhibits high electrical conductivity due to the presence of free electrons that can move through the material with relative ease. As a result, source/drain contact 242 is more likely to hold an electric charge and create an electrostatic field around itself. On the other hand, dielectric materials (e.g., dielectric layer 194) are insulators that do not conduct electric charge well. They have very low electrical conductivity because the electrons in the material are tightly bound to their parent atoms, restricting their movement. This makes it difficult for dielectric layers to hold an electric charge and create an electrostatic field. During the deposition process, the higher electrical conductivity of the source/drain contact 242 can affect the local electric field near the surface, which may help to promote the adsorption and accumulation of metal atoms, leading to the formation of metal layer 182b. In contrast, the dielectric layer 194 cannot hold a significant charge due to its insulating nature, making it less likely for the metal atoms to be adsorbed onto its surface. Consequently, the metal layer 182b is selectively formed on the back-side 242b of the source/drain contact 242 and does not form on the dielectric layer 194.

In some embodiment, a molybdenum precursor can be used in the formation of metal silicides and in a chemical vapor deposition (CVD) or atomic layer deposition (ALD) process, such that molybdenum can be deposited onto the SiGe source/drain region. During the subsequent annealing step, the deposited molybdenum reacts with the silicon and germanium atoms in the source/drain region to form the desired molybdenum silicon germanium (MoSiGe) silicide. On the other hand, when depositing the molybdenum precursor during the metal silicidation process, the molybdenum atoms in the precursor can be in a neutral state. The source/drain contact 242 is made of a conductive material, which exhibits high electrical conductivity. This means that the source/drain contact 242 may have a better ability to dissipate any local charge buildup that could occur during the deposition process. This can help create a more favorable environment for the molybdenum precursor to adsorb and accumulate on the back-side 242b of the source/drain contact 242, leading to the formation of metal layer 182b. In contrast, the dielectric layer 194 is an insulating material with low electrical conductivity. As a result, it has a reduced ability to dissipate any local charge buildup, which can lead to an unfavorable environment for the adsorption and accumulation of the molybdenum precursor. This difference in the electronic properties can contribute to the selective formation of the metal layer 182b on the back-side 242b of the source/drain contact 242 and not on the dielectric layer 194.

In some embodiment, the metal layer 182b may also be deposited on the dielectric layer, albeit with a thinner thickness compared to its deposition on the source/drain contact 242. Following the completion of the metal silicidation process, a removal step is carried out to eliminate unreacted metal on the source/drain region and to consume any residual metal in other locations, such as on the dielectric layer and atop the source/drain contact 242. Due to the difference in thickness, the metal layer 182b on the dielectric layer is entirely consumed and removed during the removal process. However, the metal layer 182b on the source/drain contact 242 is not completely consumed, as its thickness is greater than that on the dielectric layer. This results in the formation of a remaining metal layer 182b on the source/drain contact 242.

In addition, a metal cap 183b may be formed atop the metal layer 182b with the forming of the metal cap 183a by using the deposition process P5 as shown in FIGS. 15A and 15B, such as bottom-up approach, such that the metal cap 183b has a same material as the metal cap 183a. The metal cap 183b is selectively grown on the metal surface (e.g., the metal layer 182b) as the metal cap 183a, and the ILD layers 194 are substantially free from the growth of the metal caps 183a and 183b. In some embodiments, the metal cap 183b may be, by way of example and not limitation, substantially fluorine-free tungsten (FFW) films having an amount of fluorine contaminants less than 5 atomic percent. The FFW films or the FFW-comprising films may be formed by ALD or CVD using one or more non-fluorine based tungsten precursors such as, but not limited to, tungsten pentachloride (WCl₅), tungsten hexachloride (WCl₆). In some embodiments, the metal cap 183b may have a chlorine atomic concentration in a range from about 0.1 to about 5%, and thus a distinguishable interface may be formed between the metal cap 183b and the source/drain contact 244. In some embodiments, the metal layer 182b (e.g., unreacted metal layer in the metal silicidation process) as shown in FIG. 17C may be removed from the back-side 242b of the source/drain contact 242 by the etching process in the metal silicidation process described in foregoing descriptions (see FIGS. 14A and 14B), such that the metal cap 183b can be directly formed on the back-side 242b of the source/drain contact 242 as shown in FIG. 17D.

The selective formation of the metal cap 183b on the metal layer 182b, and not on the dielectric layer (e.g., ILD layer 194), can be attributed to the differences in electronic properties of the metal and the dielectric material. The metal layer 182b is a conductive material, while the dielectric layer 194 is an insulating material. The high electrical conductivity of the metal layer 182b can facilitate the adsorption and accumulation of the metal cap precursors due to the presence of a higher density of free charge carriers (electrons or holes) compared to the dielectric layer. The lower electrical conductivity of the dielectric layer makes it less likely to attract and retain the metal cap precursors. During the deposition process, the conductive metal layer 182b can maintain a more uniform charge distribution across its surface, which can provide a more favorable environment for the metal cap precursors to adsorb and react. In contrast, the dielectric layer 194 may exhibit a non-uniform charge distribution due to its insulating nature, which can hinder the adsorption and reaction of the metal cap precursors. The conductive metal layer 182b can facilitate charge transfer between the precursor species and the surface, promoting the adsorption, reaction, and bonding of the metal cap precursors to form the metal cap 183b. The insulating dielectric layer, on the other hand, has limited charge transfer capability, which can impede the formation of the metal cap 183b on its surface.

As shown FIGS. 17E and 17F, the difference between the embodiment in FIGS. 17E and 17F and the embodiment in FIGS. 17A and 17B is in that additional liners 184 and 188 may be formed to line the sidewalls 242s and 244s of the source/drain contacts 242 and 244. Specifically, before the source/drain contact 242 is formed, the liner 188 may be conformally formed over the second source/drain epitaxial structure 185 and the ILD layer 198 and to line the source/drain contact opening O1. Therefore, after the source/drain contact 242 is formed in the source/drain contact opening O1, the liner 188 may wrap around the source/drain contact 242. Similarly, before the source/drain contact 244 is formed, the liner 184 may be conformally formed over the first source/drain epitaxial structures 180 and the ILD layer 194 and to line the source/drain contact opening O2. Therefore, after the source/drain contact 244 is formed in the source/drain contact opening O2, the liner 184 may wrap around the source/drain contact 244. In some embodiments, the liner 184/188 may be a seed layer for forming the source/drain contact 242/244. By way of example and not limitation, if the source/drain contact 242/244 is made of tungsten, the liner 184/188 may be a tungsten-containing layer. In some embodiments, the liner 184/188 may be formed by physical vapor deposition by way of example but not limitation. In some embodiments, in order to avoid diffusion of metal from the source/drain contacts 242 and 244 into the ILD layers 194 and 198, the liners 184 and 188 may function as a diffusion barrier to prevent metal diffusion and as an adhesion layer between metal and dielectric. By way of example but not limitation, refractory metals, refractory metal-nitrides, refractory metal-silicon-nitrides and combinations thereof may be used for the barrier, such as TaN, Ta, Ti, TiN, TiSiN, WN, or combinations thereof. In some embodiments, the liner 184/188 may be formed by physical vapor deposition by way of example but not limitation.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a method to selectively form a metal silicide and a metal cap on a source/drain region of a transistor other than the surrounding dielectric by a deposition process, such as CVD or ALD process. As such, the deposition material of the metal silicide and the deposition material of the metal cap can be easily formed on the source/drain region through the source/drain opening in a limited deposition area. In addition, because the metal silicide and the metal cap can be only formed on the source/drain region other than the surrounding dielectric, the metal silicide and the metal cap occupy less space in the source/drain opening, which in turn facilitates the following metal filling in the source/drain opening, and thus the silicide-diffusion contact resistance of the IC structure can be improved.

In some embodiments, a method includes forming a bottom-tier transistor and a top-tier transistor over the bottom-tier transistor, the top-tier transistor comprising a first channel layer, a first gate structure around the first channel layer, and a plurality of first source/drain regions on opposite sides of the first channel layer; forming a first dielectric layer over the first source/drain regions of the top-tier transistor; etching the first dielectric layer to form a first opening exposing one of the first source/drain regions of the top-tier transistor; selectively forming a first metal silicide on the one of the first source/drain regions; selectively forming a first metal cap on the first metal silicide and not on the first dielectric layer; forming a front-side contact on the first metal cap. In some embodiments, the first metal silicide comprises TiSi or MoSiGe. In some embodiments, the first metal cap comprises a fluorine-free tungsten. In some embodiments, the first metal cap comprises a same metal element as the front-side contact. In some embodiments, the front-side contact comprises tungsten. In some embodiments, selectively forming the first metal cap is performed by a different deposition process than forming the front-side contact. In some embodiments, the bottom-tier transistor comprises a second channel layer, a second gate structure around the second channel layer, and a plurality of second source/drain regions on opposite sides of the second channel layer, the method further comprising: forming a second dielectric layer over the second source/drain regions of the bottom-tier transistor, wherein the first source/drain regions of the top-tier transistor are formed over the second dielectric layer; etching the second dielectric layer to form a second opening in the second dielectric layer, the second opening exposing one of the second source/drain regions of the bottom-tier transistor; after etching the second dielectric layer, selectively forming a second metal silicide on the one of the second source/drain regions, wherein the second metal silicide is made of a different material than the first metal silicide. In some embodiments, etching the second dielectric layer is performed until the front-side contact is exposed. In some embodiments, the method further includes selectively forming a second metal cap on the second metal silicide and not on the second dielectric layer. In some embodiments, the method further includes after selectively forming the first metal cap and prior to forming the front-side contact, forming a liner lining the first opening, the liner having a same metal element as the front-side contact.

In some embodiments, a method includes forming a first semiconductive nanostructure, and a second semiconductive nanostructure arranged in a vertical direction with the first semiconductive nanostructure; forming a plurality of first epitaxial structures on opposite sides of the first semiconductive nanostructure, and a plurality of second epitaxial structures on opposite sides of the second semiconductive nanostructure; forming a first gate wrapping around the first semiconductive nanostructure, and a second gate wrapping around the second semiconductive nanostructure; selectively forming a first metal silicide layer on one of the first epitaxial structures, and a second metal silicide layer on one of the second epitaxial structures; selectively forming a first fluorine-free metal layer on the first metal silicide layer, and a second fluorine-free metal layer on the second metal silicide layer. In some embodiments, the first epitaxial structure comprises SiGe, and the second epitaxial structure comprises SiP. In some embodiments, the second metal silicide layer has a different metal element than the first metal silicide layer. In some embodiments, the first metal silicide layer comprises MoSiGe, and the second metal silicide layer comprises TiSi. In some embodiments, the second fluorine-free metal layer is made of a same material as the first fluorine-free metal layer.

In some embodiments, a semiconductor structure includes a first transistor, a second transistor, a first metal silicide layer, a first fluorine-free tungsten layer, and a first tungsten contact. The first transistor includes a plurality of first semiconductor sheets, a first gate structure surrounding each of the first semiconductor sheets, and a plurality of first source/drain structures on either side of each of the first semiconductor sheets. The second transistor is over the first transistor. The second transistor includes a plurality of second semiconductor sheets, a second gate structure surrounding each of the second semiconductor sheets, a plurality of second source/drain structures on either side of each of the second semiconductor sheets. The first metal silicide layer is on one of the first source/drain structures. The first fluorine-free tungsten layer is on the first metal silicide layer. The first tungsten contact is on the first fluorine-free tungsten layer. In some embodiments, the semiconductor structure further includes a tungsten liner lining a sidewall of the first tungsten contact. In some embodiments, there is no metal nitride between the first tungsten contact and the one of the first source/drain structures. In some embodiments, the semiconductor structure further includes a second metal silicide layer, a second fluorine-free tungsten layer, and a second tungsten contact. The second metal silicide layer is on one of the second source/drain structures. The second fluorine-free tungsten layer is on the second metal silicide layer. The second tungsten contact is on the second fluorine-free tungsten layer. In some embodiments, the first tungsten contact has a first cross-sectional profile and a second cross-sectional profile between the first cross-sectional profile and the first fluorine-free tungsten layer, the second tungsten contact has a third cross-sectional profile and a fourth cross-sectional profile between the third cross-sectional profile and the second fluorine-free tungsten layer, the first cross-sectional profile has a wider width than the second cross-sectional profile, and the third cross-sectional profile has a wider width than the fourth cross-sectional profile.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a bottom-tier transistor and a top-tier transistor over the bottom-tier transistor, the top-tier transistor comprising a first channel layer, a first gate structure around the first channel layer, and a plurality of first source/drain regions on opposite sides of the first channel layer;
forming a first dielectric layer over the first source/drain regions of the top-tier transistor;
etching the first dielectric layer to form a first opening exposing one of the first source/drain regions of the top-tier transistor;
selectively forming a first metal silicide on the one of the first source/drain regions;
selectively forming a first metal cap on the first metal silicide and not on the first dielectric layer; and
forming a front-side contact on the first metal cap.

2. The method of claim 1, wherein the first metal silicide comprises TiSi or MoSiGe.

3. The method of claim 1, wherein the first metal cap comprises a fluorine-free tungsten.

4. The method of claim 1, wherein the first metal cap comprises a same metal element as the front-side contact.

5. The method of claim 1, wherein the front-side contact comprises tungsten.

6. The method of claim 1, wherein selectively forming the first metal cap is performed by a different deposition process than forming the front-side contact.

7. The method of claim 1, wherein the bottom-tier transistor comprises a second channel layer, a second gate structure around the second channel layer, and a plurality of second source/drain regions on opposite sides of the second channel layer, the method further comprising:
forming a second dielectric layer over the second source/drain regions of the bottom-tier transistor, wherein the first source/drain regions of the top-tier transistor are formed over the second dielectric layer;
etching the second dielectric layer to form a second opening in the second dielectric layer, the second opening exposing one of the second source/drain regions of the bottom-tier transistor; and
after etching the second dielectric layer, selectively forming a second metal silicide on the one of the second source/drain regions, wherein the second metal silicide is made of a different material than the first metal silicide.

8. The method of claim 7, wherein etching the second dielectric layer is performed until the front-side contact is exposed.

9. The method of claim 7, further comprising:
selectively forming a second metal cap on the second metal silicide and not on the second dielectric layer.

10. The method of claim 1, further comprising:
after selectively forming the first metal cap and prior to forming the front-side contact, forming a liner lining the first opening, the liner having a same metal element as the front-side contact.

11. A method, comprising:
forming a first semiconductive nanostructure, and a second semiconductive nanostructure arranged in a vertical direction with the first semiconductive nanostructure;
forming a plurality of first epitaxial structures on opposite sides of the first semiconductive nanostructure, and a plurality of second epitaxial structures on opposite sides of the second semiconductive nanostructure;
forming a first gate wrapping around the first semiconductive nanostructure, and a second gate wrapping around the second semiconductive nanostructure;
selectively forming a first metal silicide layer on one of the first epitaxial structures, and a second metal silicide layer on one of the second epitaxial structures; and
selectively forming a first fluorine-free metal layer on the first metal silicide layer, and a second fluorine-free metal layer on the second metal silicide layer.

12. The method of claim 11, wherein the first epitaxial structures comprise SiGe, and the second epitaxial structures comprise SiP.

13. The method of claim 11, wherein the second metal silicide layer has a different metal element than the first metal silicide layer.

14. The method of claim 11, wherein the first metal silicide layer comprises MoSiGe, and the second metal silicide layer comprises TiSi.

15. The method of claim 11, wherein the second fluorine-free metal layer is made of a same material as the first fluorine-free metal layer.

16. A semiconductor structure, comprising:
a first transistor comprising:
a plurality of first semiconductor sheets;
a first gate structure surrounding each of the first semiconductor sheets; and
a plurality of first source/drain structures on either side of each of the first semiconductor sheets;
a second transistor over the first transistor, the second transistor comprising:
a plurality of second semiconductor sheets;
a second gate structure surrounding each of the second semiconductor sheets; and
a plurality of second source/drain structures on either side of each of the second semiconductor sheets;
a first metal silicide layer on one of the first source/drain structures;
a first fluorine-free tungsten layer on the first metal silicide layer; and
a first tungsten contact on the first fluorine-free tungsten layer.

17. The semiconductor structure of claim 16, further comprising:
a tungsten liner lining a sidewall of the first tungsten contact.

18. The semiconductor structure of claim 16, wherein there is no metal nitride between the first tungsten contact and the one of the first source/drain structures.

19. The semiconductor structure of claim 16, further comprising:
a second metal silicide layer on one of the second source/drain structures;
a second fluorine-free tungsten layer on the second metal silicide layer; and
a second tungsten contact on the second fluorine-free tungsten layer.

20. The semiconductor structure of claim 19, wherein the first tungsten contact has a first cross-sectional profile and a second cross-sectional profile between the first cross-sectional profile and the first fluorine-free tungsten layer, the second tungsten contact has a third cross-sectional profile and a fourth cross-sectional profile between the third cross-sectional profile and the second fluorine-free tungsten layer, the first cross-sectional profile has a wider width than the second cross-sectional profile, and the third cross-sectional profile has a wider width than the fourth cross-sectional profile.
